(19) United States
(12) Patent Application Publication
(10) Pub. No.: US 2012/0075962 A1
(43) Pub. Date: Mar. 29, 2012

(54) PIEZOELECTRIC VIBRATION PIECE, PIEZOELECTRIC VIBRATOR, OSCILLATOR, ELECTRONIC DEVICE AND RADIO-CONTROLLED TIMEPIECE

(76) Inventor: Daishi Arimatsu, Chiba-shi (JP)

(21) Appl. No.: 13/234,709

(22) Filed: Sep. 16, 2011

(30) Foreign Application Priority Data
Sep. 29, 2010 (JP) 2010-219008

(51) Int. Cl. G04C 11/02; H03B 5/32; H01L 41/04

(52) U.S. Cl. 368/47; 310/370; 331/158

(57) ABSTRACT

The present invention provides a piezoelectric vibration piece of tuning fork type which comprises a pair of arms extending in parallel to each other from a base. Each of the arms has a weight added section which has at least two bulges projecting in the opposite directions at different longitudinal locations along the respective arm, and the at least two bulges are shaped and located such that both arms are equal in weight and a gravity center of the respective arms is situated on a center line running longitudinally through the respective arms and at a same longitudinal location along the respective arms.

### RELATED APPLICATIONS

This application claims priority under 35 U.S.C. §119 to Japanese Patent Application No. 2010-219008 filed on Sep. 29, 2010, the entire content of which is hereby incorporated by reference.

### BACKGROUND OF THE INVENTION

1. Field of the Invention

The present invention relates to a piezoelectric vibration piece, a piezoelectric vibrator, an oscillator, an electronic device and a radio-controlled timepiece.

2. Description of the Related Art

In recent years, a piezoelectric vibrator utilizing a crystal or the like has been used as a time source, a timing source for control signals, a reference signal source or the like for mobile phones and portable information terminal devices. Various piezoelectric vibrators of this type have been provided. As one of them, a piezoelectric vibrator having what is called a tuning-fork type piezoelectric vibration piece is known.

The tuning-fork type piezoelectric vibration piece includes: a first vibrating arm and a second vibrating arm extending in the longitudinal direction and arranged in the width direction; and a base to which the base-end side of the both vibrating arms are connected, the vibrating arms being configured to vibrate (swing) at a predetermined resonance frequency in the direction in which the tips of the vibrating arms move close to or away from each other with the base-end side as starting point.

By the way, in recent years, the piezoelectric vibration piece needs to be downsized as mobile phones and portable information terminal devices become downsized. One method for this may be to shorten the vibrating arms, but this method have a problem that the resonance frequency of the piezoelectric vibration piece may exceed a predetermined resonance frequency.

In order to solve this problem, a piezoelectric vibration piece described in JP-A-2007-13910 may be used. This piezoelectric vibration piece includes vibrating arms having step parts. The vibrating arms extend from the base-end side to the step parts with a constant width and from the step parts to the tip side with a width wider than the constant width. In each vibrating arm, the step part bulges on both sides of the width direction, and a tip portion positioned on the tip side with respect to the step part has a width wider than that of a portion positioned on the base-end side with respect to the step part. This increases the mass of the tip portion, allowing decreasing of the resonance frequency of the piezoelectric vibration piece by the effect of weighting, which facilitates ensuring of a predetermined resonance frequency.

However, in the above-described conventional piezoelectric vibration piece, the width of the tip portions is wider, so the space between the tip portions of the vibrating arms may become too narrow, causing the tip portions to be in contact with each other when the vibrating arms vibrate.

One method for solving this problem may be to increase the space between the vibrating arms in the width direction to shift the tip portions of the vibrating arms away from each other in the width direction. But, this method may increase the size in the width direction of the piezoelectric vibration piece, leading to difficulty in achieving the original goal of downsizing the piezoelectric vibration piece.

In view of the above, it is an object of the invention to provide a piezoelectric vibration piece that can be downsized while ensuring a predetermined resonance frequency.

### SUMMARY OF THE INVENTION

In order to achieve the above object, the invention proposes the following means.

A piezoelectric vibration piece in accordance with the invention is a tuning-fork type piezoelectric vibration piece including: a first vibrating arm and a second vibrating arm extending in the longitudinal direction and arranged in the width direction; and a base to which the base-end side of the both vibrating arms are connected, wherein, in a tip portion of the first vibrating arm, a first inwardly bulging portion that bulges inwardly in the width direction and a first outwardly bulging portion that bulges outwardly in the width direction are formed, wherein, in a tip portion of the second vibrating arm, a second inwardly bulging portion that bulges inwardly in the width direction and a second outwardly bulging portion that bulges outwardly in the width direction are formed, wherein, in a portion of the first vibrating arm opposite the second inwardly bulging portion in the width direction, a first relief portion is provided that is depressed in the width direction outwardly from a bulging-end edge of the first inwardly bulging portion, and wherein, in a portion of the second vibrating arm opposite the first inwardly bulging portion in the width direction, a second relief portion is provided that is depressed in the width direction outwardly from a bulging-end edge of the second inwardly bulging portion.

According to this invention, including the first inwardly bulging portion, the first outwardly bulging portion, second inwardly bulging portion and the second outwardly bulging portion can increase the masses of the tip portions of the vibrating arms to decrease the resonance frequency of the piezoelectric vibration piece by the effect of weighting. This facilitates ensuring of the predetermined resonance frequency even if the vibrating arms are shortened.

Also, since the first relief portion is provided in the portion of the first vibrating arm opposite to the second inwardly bulging portion in the width direction, and the second relief portion is provided in the portion of the second vibrating arm opposite to the first inwardly bulging portion in the width direction, forming the first inwardly bulging portion and the second inwardly bulging portion can prevent the clearance in the width direction between the tip portions of the vibrating arms from being too small, facilitating ensuring of the clearance. Accordingly, with the vibrating arms close to each other in the width direction, the tip portions can be prevented from being in contact with each other when the vibrating arms vibrate.

Then, since, with the vibrating arms close to each other in the width direction, the tip portions can be thus prevented from being in contact with each other when the vibrating arms vibrate, the size in the width direction of the piezoelectric vibration piece can be reduced while the vibrating arms being shortened, facilitating downsizing of the piezoelectric vibrator.

Also, the amount of depression of the first relief portion may be equal to the amount of bulge of the second inwardly bulging portion over the entire length in the longitudinal direction, and the amount of depression of the second relief portion may be equal to the amount of bulge of the first inwardly bulging portion over the entire length in the longitudinal direction.

In this case, since the amount of depression of the first relief portion may be equal to the amount of bulge of the second inwardly bulging portion over the entire length in the longitudinal direction, and the amount of depression of the second relief portion may be equal to the amount of bulge of the first inwardly bulging portion over the entire length in the longitudinal direction, forming the first inwardly bulging portion and the second inwardly bulging portion can surely prevent the clearance in the width direction between the tip portions of the vibrating arms from being too small, further facilitating ensuring of the clearance.

Also, thus, the amount of depression of the first relief portion may equal to the amount of bulge of the second inwardly bulging portion over the entire length in the longitudinal direction, and the amount of depression of the second relief portion may be equal to the amount of bulge of the first inwardly bulging portion over the entire length in the longitudinal direction, so the first relief portion and the second relief portion may not excessively depressed in the width direction. Accordingly, the masses of the tip portions of the vibrating arms can be surely increased.

Also, by forming the first outwardly bulging portion and the second outwardly bulging portion according to the first inwardly bulging portion and the second inwardly bulging portion, the centers of gravity of the vibrating arms may be positioned on the respective central axis lines of the vibrating arms; the positions in the longitudinal direction of the centers of gravity may be the same; and the masses of the vibrating arms may be equal.

In this case, since, by forming the first outwardly bulging portion and the second outwardly bulging portion according to the first inwardly bulging portion and the second inwardly bulging portion, the centers of gravity of the vibrating arms may be positioned on the respective central axis lines of the vibrating arms; the positions in the longitudinal direction of the centers of gravity may be the same; and the masses of the vibrating arms may be equal, the outwardly bulging portions may allow the eigen frequencies of the vibrating arms to be equal, facilitating ensuring of a good vibration characteristics of the piezoelectric vibration piece.

Also, the first inwardly bulging portion and the second inwardly bulging portion may be opposite to each other in the width direction; the amounts of bulge of these inwardly bulging portions may individually depend on the position in the longitudinal direction; and by forming the bulging surfaces of the inwardly bulging portions facing toward the inside in the width direction in a shape that follows each other, the first relief portions and the second relief portions may be provided with the respective bulging surfaces as the wall surfaces.

In this case, by forming the bulging surfaces of the inwardly bulging portions in a shape that follows each other, the first relief portions and the second relief portions may be provided with the respective bulging surfaces as the wall surfaces, which may eliminate the need for making the positions in the longitudinal direction of the first inwardly bulging portions and the second inwardly bulging portions different from each other, allowing a plurality of the inwardly bulging portions to be formed continuously in the longitudinal direction in the tip portions of the vibrating arms.

Also, it is allowed that the amount of bulge of one of the first inwardly bulging portion and the second inwardly bulging portion gradually increases from the both ends to the center in the longitudinal direction and the amount of bulge of the other gradually decreases from the both ends to the center in the longitudinal direction.

In this case, since, it is allowed that the amount of bulge of the one gradually increases from the both ends to the center in the longitudinal direction and the amount of bulge of the other gradually decreases from the both ends to the center in the longitudinal direction, the both ends in the longitudinal direction of the one may be chamfered, which can further prevent the tip portions from being in contact with each other when the vibrating arms vibrate.

Also, on the main surfaces of the tip portions facing in the direction perpendicular to the width direction and the longitudinal direction, weight films may be formed.

In this case, the weight films that may be formed on the main surfaces of the tip portions in combination with the inwardly bulging portions and the outwardly bulging portions provided in the tip portions can effectively increase the masses of the tip portions of the vibrating arms.

A piezoelectric vibrator of the invention includes the above-described piezoelectric vibration piece.

According to the invention, including the piezoelectric vibration piece can prevent the tip portions of the vibrating arms from being in contact with each other when the vibrating arms vibrate, improving the quality and facilitating downsizing of the piezoelectric vibrator.

An oscillator of the invention includes the above-described piezoelectric vibrator as resonator electrically connected to an integrated circuit.

An electronic device of the invention includes the above-described piezoelectric vibrator electrically connected to a timer.

A radio-controlled timepiece of the invention includes the above-described piezoelectric vibrator electrically connected to a filter.

According to the oscillator, electronic device and radio-controlled timepiece in accordance with the invention, including the above-described piezoelectric vibrator allows manufacturing of the oscillator, electronic device and radio-controlled timepiece with high quality and small size.

According to the piezoelectric vibration piece in accordance with the invention, the piezoelectric vibration piece can be downsized while ensuring a predetermined resonance frequency.

Also, according to the piezoelectric vibrator, the oscillator, electronic device and radio-controlled timepiece in accordance with the invention, improving the quality and facilitating downsizing of the piezoelectric vibrator, the oscillator, electronic device and radio-controlled timepiece can be performed.

### BRIEF DESCRIPTION OF THE DRAWINGS

FIG. 1 is a plan view of a piezoelectric vibrator in accordance with an embodiment of the invention;

FIG. 2 is an enlarged plan view of tip portions of vibrating arms of a piezoelectric vibration piece included in the piezoelectric vibrator shown in FIG. 1;

FIG. 3 is a cross-sectional arrow view along the line A-A in FIG. 1;

FIG. 4 is a cross-sectional arrow view along the line B-B in FIG. 1;

FIG. 5 is a plan view of a piezoelectric vibration piece in accordance with a first variation of the invention;

FIG. 6 is a plan view of a piezoelectric vibration piece in accordance with a second variation of the invention;

FIG. 7 is an enlarged plan view of tip portions of vibrating arms of the piezoelectric vibration piece shown in FIG. 6;

FIG. 8 is a plan view of a piezoelectric vibration piece in accordance with a third variation of the invention;

FIG. 9 is a configuration diagram showing an oscillator in accordance with an embodiment of the invention;

FIG. 10 is a configuration diagram showing an electronic device in accordance with an embodiment of the invention;

FIG. 11 is a configuration diagram showing a radio-controlled timepiece in accordance with an embodiment of the invention;

FIG. 12 is a front view showing a piezoelectric vibrator in accordance with a variation of the invention;

FIG. 13 is a side view of the piezoelectric vibrator shown in FIG. 12;

FIG. 14 is a plan view of a piezoelectric vibration piece in accordance with a variation of the invention;

FIG. 15 is a plan view of a piezoelectric vibration piece in accordance with a variation of the invention; and

FIG. 16 is a plan view of a piezoelectric vibration piece in accordance with a variation of the invention.

### DETAILED DESCRIPTION OF THE PREFERRED EMBODIMENTS

### Piezoelectric Vibrator

A piezoelectric vibrator in accordance with an embodiment of the invention is described below with reference to the drawings.

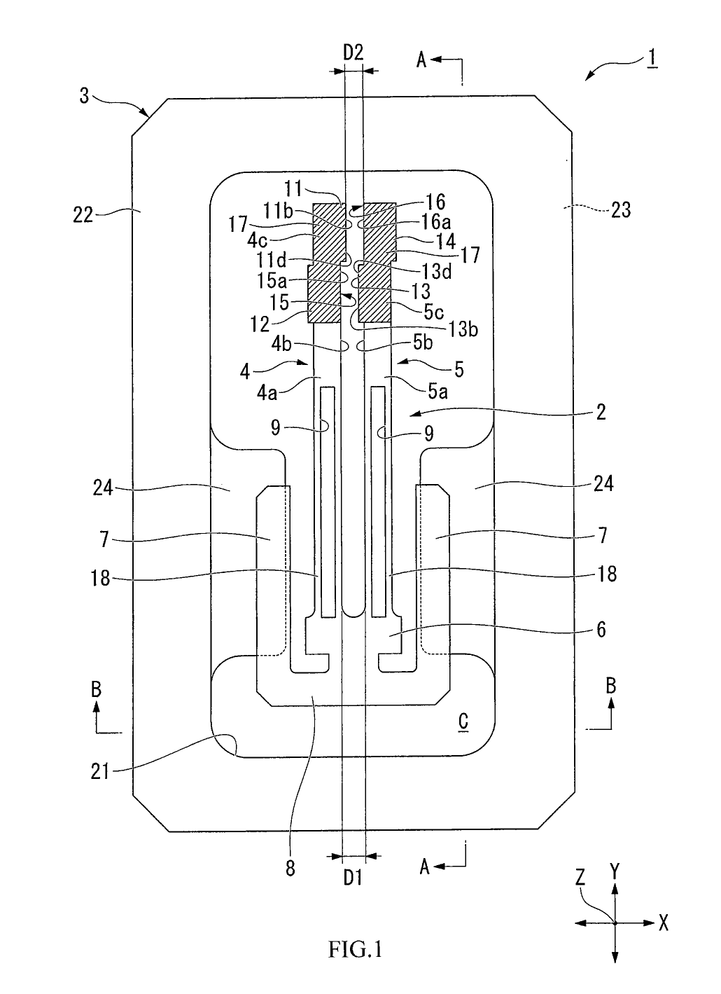

As shown in FIG. 1, a piezoelectric vibrator 1, which is what is called a surface-mount type, includes: a tuning-fork type piezoelectric vibration piece 2; and a package 3 having a cavity C for containing the piezoelectric vibration piece 2.

The piezoelectric vibration piece 2 includes: a first vibrating arm 4 and a second vibrating arm 5 extending in the longitudinal direction Y and arranged in the width direction X; a base 6 to which the base-end side of the vibrating arms 4, 5 are connected; and a pair of side bases 7 spaced in the width direction X with the base 6 and base-end portions 18 of the vibrating arms 4, 5 in between and with the base-end side connected to the base 6. The piezoelectric vibration piece 2 is integrally formed of, for example, a piezoelectric material, such as quartz, lithium tantalate and lithium niobate, and, when a predetermined voltage is applied, the vibrating arms 4, 5 vibrate.

In the following, the tip side of the vibrating arms 4, 5 in the longitudinal direction Y is referred to as one side, and the base-end side of the vibrating arms 4, 5 is referred to as the other side.

The base 6 is in a rectangular shape having a longer side in the width direction X in plan view from the normal direction Z perpendicular to the width direction X and the longitudinal direction Y. The vibrating arms 4, 5 are connected to one end surface of the base 6 facing toward the one side.

Each of the side bases 7 extends in the longitudinal direction Y with the base-end side of each of the side bases 7 connected to the base 6 through a connection part 8. The connection part 8 extends in the width direction X and is connected to an end surface of the base 6 opposite the one end surface, which provides a space in the width direction X between the side bases 7 and the base 6 and vibrating arms 4, 5.

The vibrating arms 4, 5 have a rectangular shape in a vertical cross section view in the width direction X. Also, in the vibrating arms 4, 5, grooves 9 extending in the longitudinal direction Y are formed in main surfaces 4a, 5a facing toward the normal direction Z, respectively. The grooves 9 are formed from the base ends of the vibrating arms 4, 5 to the center in the longitudinal direction Y of the vibrating arms 4, 5.

Also, in a tip portion 4c of the first vibrating arm 4 (the vibrating arm to the left in FIG. 1), a first inwardly bulging portion 11 that bulges inwardly in the width direction X and a first outwardly bulging portion 12 that bulges outwardly in the width direction X are formed. Also, in a tip portion 5c of the second vibrating arm 5 (the vibrating arm to the right in FIG. 1), a second inwardly bulging portion 13 that bulges inwardly in the width direction X and a second outwardly bulging portion 14 that bulges outwardly in the width direction X are formed.

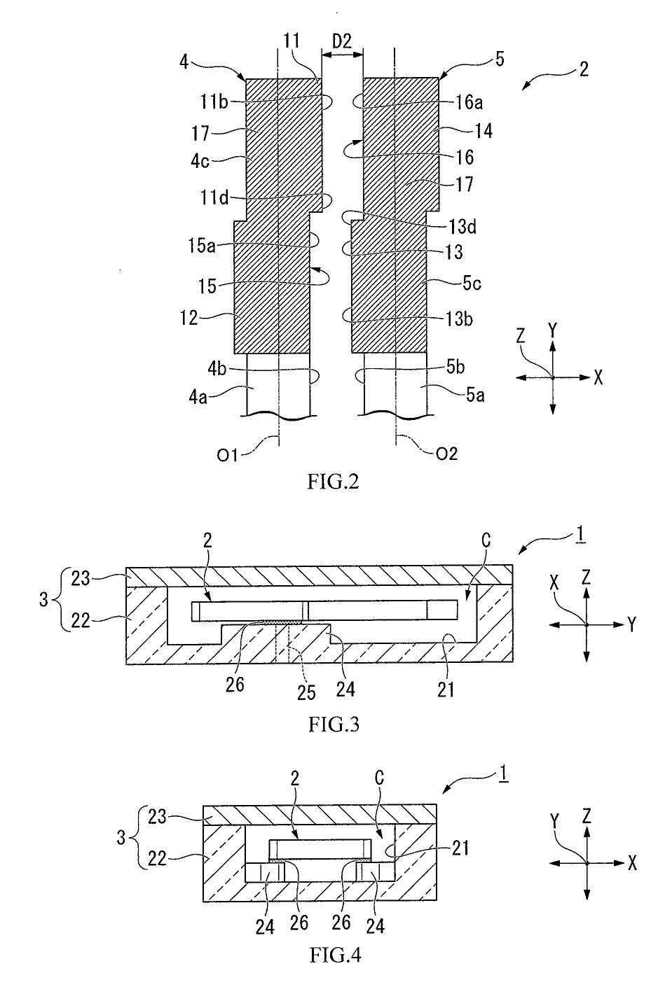

As shown in FIG. 2, the first inwardly bulging portion 11 and the second inwardly bulging portion 13 are formed in the same size and same rectangular shape having a longer side in the longitudinal direction Y in the plan view. Accordingly, a first spacing distance by which the center of gravity of the first inwardly bulging portion 11 is spaced in the width direction X from an inner side surface 4b of the first vibrating arm 4 facing toward the inside in the width direction X is equal to a second spacing distance by which the center of gravity of the second inwardly bulging portion 13 is spaced in the width direction X from an inner side surface 5b of the second vibrating arm 5 facing toward the inside in the width direction X.

Then, in a portion of the first vibrating arm 4 opposite the second inwardly bulging portion 13 in the width direction X, a first relief portion 15 is provided that is depressed in the width direction X outwardly from a bulging-end edge 11b of the first inwardly bulging portion 11. Also, in a portion of the second vibrating arm 5 opposite the first inwardly bulging portion 11 in the width direction X, a second relief portion 16 is provided that is depressed in the width direction X outwardly from a bulging-end edge 13b of the second inwardly bulging portion 13.

In the embodiment, the positions in the longitudinal direction Y of the inwardly bulging portions 11, 13 are different from each other. The inwardly bulging portions 11, 13 are not opposite to each other over the entire length in the longitudinal direction Y, thereby providing the first relief portion 15 and the second relief portion 16. The first inwardly bulging portion 11 and the first relief portion 15 are arranged in the longitudinal direction Y. Also, the second inwardly bulging portion 13 and second relief portion 16 are arranged in the longitudinal direction Y.

The amount of depression of the first relief portion 15 is equal to the amount of bulge of the second inwardly bulging portion 13 over the entire length in the longitudinal direction Y. Then, a wall surface 15a of the first relief portion 15 is formed in a shape that follows the shape of a bulging surface 13d of the second inwardly bulging portion 13 facing toward the inside in the width direction X. Also, the amount of depression of the second relief portion 16 is equal to the amount of bulge of the first inwardly bulging portion 11 over the entire length in the longitudinal direction Y. Then, a wall surface 16a of the second relief portion 16 is formed in a shape that follows the shape of a bulging surface 11d of the first inwardly bulging portion 11 facing toward the inside in the width direction X. Accordingly, a clearance D2 in the width direction X between the tip portions 4c, 5c of the vibrating arms 4, 5 is constant over the entire length in the longitudinal direction Y.

Also, the first outwardly bulging portion 12 and the second outwardly bulging portion 14 are formed according to the first inwardly bulging portion 11 and the second inwardly bulging portion 13. Accordingly, the centers of gravity of the vibrating arms 4, 5 are positioned on central axis lines O1, O2 of the vibrating arms 4, 5, respectively; the positions in the longitudinal direction Y of the centers of gravity are the same; and the masses of the vibrating arms 4, 5 are equal.

In the embodiment, the first outwardly bulging portion 12 is at the same position in the longitudinal direction Y as the second inwardly bulging portion 13, and is formed in the same size and same shape as the second inwardly bulging portion 13. Thus, since the first outwardly bulging portion 12 is formed in the same size and same shape as the second inwardly bulging portion 13, the distance by which the center of gravity of the first outwardly bulging portion 12 is spaced in the width direction X from an outer side surface of the first vibrating arm 4 facing toward the outside in the width direction X is equal to the second spacing distance. Note that, since the second spacing distance is equal to the first spacing distance by which the center of gravity of the first inwardly bulging portion 11 is spaced in the width direction X from the inner side surface 4b of the first vibrating arm 4, the center of gravity of the first vibrating arm 4 is positioned on the central axis line O1 of the first vibrating arm 4.

Also, the second outwardly bulging portion 14 is at the same position in the longitudinal direction Y as the first inwardly bulging portion 11, and is formed in the same size and same shape as the first inwardly bulging portion 11. Since the second outwardly bulging portion 14 is formed in the same size and same shape as the first inwardly bulging portion 11, the distance by which the center of gravity of the second outwardly bulging portion 14 is spaced in the width direction X from an outer side surface of the second vibrating arm 5 facing toward the outside in the width direction X is equal to the first spacing distance. Note that, since the first spacing distance is equal to the second spacing distance, the center of gravity of the second vibrating arm 5 is positioned on the central axis line O2 of the second vibrating arm 5.

Furthermore, since the first outwardly bulging portion 12 is at the same position in the longitudinal direction Y as the second inwardly bulging portion 13 and is formed in the same size and same shape as the second inwardly bulging portion 13, and the second outwardly bulging portion 14 is at the same position in the longitudinal direction Y as the first inwardly bulging portion 11 and is formed in the same size and same shape as the first inwardly bulging portion 11, the first vibrating arm 4 and the second vibrating arm 5 are in the same size and same shape. Accordingly, the masses of the vibrating arms 4, 5 are equal, and the positions in the longitudinal direction Y of the centers of gravity of the vibrating arms 4, 5 are the same.

Also, on the main surfaces 4a, 5a of the tip portions 4c, 5c of the vibrating arms 4, 5, weight metal films (weight films) 17 for frequency adjustment are formed. After being formed on the main surfaces 4a, 5a, the weight metal films 17 are partially removed from the main surfaces 4a, 5a by being irradiated with, e.g., laser light. This adjusts the resonance frequencies of the vibrating arms 4, 5.

Furthermore, on an outer surface of the piezoelectric vibration piece 2, electrode films not shown are formed to cause the vibrating arms 4, 5 to vibrate at a predetermined resonance frequency in the direction in which the vibrating arms 4, 5 move close to or away from each other. The electrode films are not electrically connected to the weight metal films 17 and have mount portions placed on the tip portions of the side bases 7.

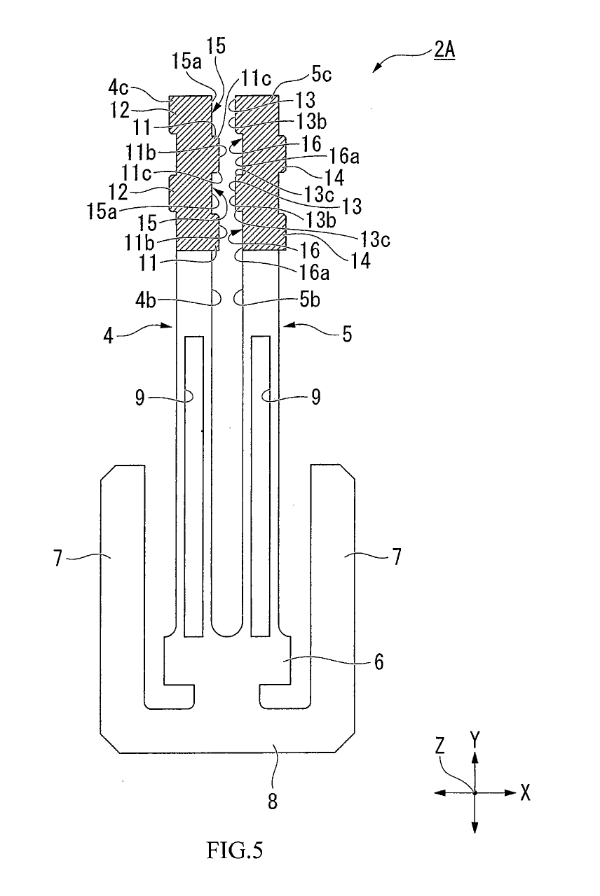

As shown in FIGS. 3 and 4, the package 3 is formed by bonding a base substrate 22 in which a concave portion for cavity 21 is formed and a lid substrate 23 for sealing the concave portion 21 to form the cavity C.

The base substrate 22 is formed of, for example, an insulating material such as ceramic. On portions of the bottom surface of the concave portion 21 located on both outer sides in the width direction X, a pair of seatings 24 connected to side surfaces of the concave portion 21 are projected.

Also, as shown in FIG. 3, through electrodes 25 for electrically connecting the inside of the cavity C and the outside are formed in the base substrate 22. In the shown example, the through electrodes 25 pass through the seatings 24 in the normal direction Z. The through electrodes 25 are connected to external electrodes not shown on the bottom surface of the base substrate 22. Then, onto the through electrodes 25, the mount portions of the piezoelectric vibration piece 2 are mounted from the inside of the cavity C via a conductive adhesive 26.

The lid substrate 23 is formed of, for example, a metallic material and have an outer circumference portion bonded to an outer circumference portion of the base substrate 22. Note that the base substrate 22 and the lid substrate 23 may be bonded via a bonding film not shown, for example.

In order to activate the piezoelectric vibrator 1 thus configured, a predetermined drive voltage is applied to the external electrodes. This can apply the voltage to the electrode films of the piezoelectric vibration piece 2, which can cause the vibrating arms 4, 5 to vibrate at a predetermined frequency in the direction in which the vibrating arms 4, 5 move close to or away from each other. Then, using the vibration of the vibrating arms 4, 5 allows the piezoelectric vibrator 1 to be used for a time source, a timing source for control signals, a reference signal source or the like.

As described above, according to the piezoelectric vibration piece 2 in accordance with the embodiment, including the first inwardly bulging portion 11, the first outwardly bulging portion 12, second inwardly bulging portion 13 and the second outwardly bulging portion 14 can increase the masses of the tip portions 4c, 5c of the vibrating arms 4, 5 to decrease the resonance frequency of the piezoelectric vibration piece 2 by the effect of weighting. This facilitates ensuring of the predetermined resonance frequency even if the vibrating arms 4, 5 are shortened.

Also, since the first relief portion 15 is provided in the portion of the first vibrating arm 4 opposite to the second inwardly bulging portion 13 in the width direction X, and the second relief portion 16 is provided in the portion of the second vibrating arm 5 opposite to the first inwardly bulging portion 11 in the width direction X, forming the first inwardly bulging portion 11 and the second inwardly bulging portion 13 can prevent the clearance D2 in the width direction X between the tip portions 4c, 5c of the vibrating arms 4, 5 from being too small, facilitating ensuring of the clearance D2. Accordingly, with the vibrating arms 4, 5 close to each other in the width direction X, the tip portions 4c, 5c can be prevented from being in contact with each other when the vibrating arms 4, 5 vibrate.

Then, since, with the vibrating arms 4, 5 close to each other in the width direction X, the tip portions 4c, 5c can be thus prevented from being in contact with each other when the vibrating arms 4, 5 vibrate, the size in the width direction X of the piezoelectric vibration piece 2 can be reduced while the vibrating arms 4, 5 being shortened, facilitating downsizing of the piezoelectric vibrator 1.

Also, when the piezoelectric vibration piece 2 includes the pair of side bases 7 as in the embodiment, placing the vibrating arms 4, 5 close to each other in the width direction X to reduce a clearance D1 between the base-end portions 18 of the vibrating arms 4, 5 can inhibit vibration leakage due to the vibration of the vibrating arms 4, 5 to the side bases 7.

Specifically, in the vibrating arms 4, 5 in the shown example, the clearance D1 in the width direction X between the base-end portions 18 is, for example, about 100 μm, and the clearance D2 in the width direction X between the tip portions 4c, 5c is, for example, about 80-90 μm.

Also, since the amount of depression of the first relief portion 15 is equal to the amount of bulge of the second inwardly bulging portion 13 over the entire length in the longitudinal direction Y, and the amount of depression of the second relief portion 16 is equal to the amount of bulge of the first inwardly bulging portion 11 over the entire length in the longitudinal direction Y, forming the first inwardly bulging portion 11 and the second inwardly bulging portion 13 can surely prevent the clearance D2 in the width direction X between the tip portions 4c, 5c of the vibrating arms 4, 5 from being too small, further facilitating ensuring of the clearance D2.

Also, thus, the amount of depression of the first relief portion 15 is equal to the amount of bulge of the second inwardly bulging portion 13 over the entire length in the longitudinal direction Y, and the amount of depression of the second relief portion 16 is equal to the amount of bulge of the first inwardly bulging portion 11 over the entire length in the longitudinal direction Y, so the first relief portion 15 and the second relief portion 16 are not excessively depressed in the width direction X. Accordingly, the masses of the tip portions 4c, 5c of the vibrating arms 4, 5 can be surely increased.

Also, the weight metal films 17 formed on the main surfaces 4a, 5a of the tip portions 4c, 5c in combination with the inwardly bulging portions 11, 13 and the outwardly bulging portions 12, 14 provided in the tip portions 4c, 5c can effectively increase the masses of the tip portions 4c, 5c of the vibrating arms 4, 5.

Also, since the first outwardly bulging portion 12 and the second outwardly bulging portion 14 are formed according to the first inwardly bulging portion 11 and the second inwardly bulging portion 13, the centers of gravity of the vibrating arms 4, 5 are positioned on the central axis lines O1, O2 of the vibrating arms 4, 5, respectively; the positions in the longitudinal direction Y of the centers of gravity are the same; and the masses of the vibrating arms 4, 5 are equal. So, the outwardly bulging portions 12, 14 allows the eigen frequencies of the vibrating arms 4, 5 to be equal, facilitating ensuring of a good vibration characteristics of the piezoelectric vibration piece 2.

Then, according to the piezoelectric vibrator 1 in accordance with the embodiment, including the piezoelectric vibration piece 2 can prevent the tip portions 4c, 5c of the vibrating arms 4, 5 from being in contact with each other when the vibrating arms 4, 5 vibrate, improving the quality and facilitating downsizing of the piezoelectric vibrator 1.

### (Variation)

Next, first and second variations of the piezoelectric vibration piece in accordance with the invention are described.

Note that, for these variations, components like those of the above-described embodiment are denoted by like numerals and will not be repeatedly described, and only different components are described.

First, a piezoelectric vibration piece 2A of the first variation is described with reference to FIG. 5.

In the piezoelectric vibration piece 2A, a plurality of the first inwardly bulging portions 11 and a plurality of the second inwardly bulging portions 13 are formed in the longitudinal direction Y, the numbers of the formed inwardly bulging portions 11, 13 being equal, which is two in the shown example.

The first inwardly bulging portions 11 and the second inwardly bulging portions 13 are placed at staggered positions in the longitudinal direction Y. The spacing between the first inwardly bulging portions 11 adjacent to each other in the longitudinal direction Y is equal to the size in the longitudinal direction Y of the second inwardly bulging portion 13, and the spacing between the second inwardly bulging portions 13 adjacent to each other in the longitudinal direction Y is equal to the size in the longitudinal direction Y of the first inwardly bulging portion 11. Accordingly, the first relief portions 15 are provided in portions of the first vibrating arm 4 opposite to the second inwardly bulging portions 13 in the width direction X, and the second relief portions 16 are provided in portions of the second vibrating arm 5 opposite to the first inwardly bulging portions 11 in the width direction X.

Note that one of the first relief portions 15 that is positioned between the first inwardly bulging portions 11 adjacent to each other in the longitudinal direction Y forms a concave shape depressed between these first inwardly bulging portions 11. Also one of the second relief portions 16 that is positioned between the second inwardly bulging portions 13 adjacent to each other in the longitudinal direction Y forms a concave shape depressed between these second inwardly bulging portions 13.

Also, in the shown example, chamfered portions 11c, 13c are formed in the corners of end surfaces facing in the longitudinal direction Y of the first inwardly bulging portions 11 and the second inwardly bulging portions 13, respectively. Note that the chamfered portions 11c, 13c are optional.

Also, the same numbers of the first outwardly bulging portions 12 and second outwardly bulging portions 14 as those of the first inwardly bulging portions 11 and second inwardly bulging portions 13, respectively, the number being two in the shown example, are formed. As described above, the first outwardly bulging portions 12 are at the same positions in the longitudinal direction Y as the second inwardly bulging portions 13. Accordingly, the first inwardly bulging portions 11 and the first outwardly bulging portion 12 are placed at staggered positions in the longitudinal direction Y. Also, as described above, the second outwardly bulging portions 14 are at the same positions in the longitudinal direction Y as the first inwardly bulging portions 11. Accordingly, the second inwardly bulging portions 13 and the second outwardly bulging portions 14 are placed at staggered positions in the longitudinal direction Y.

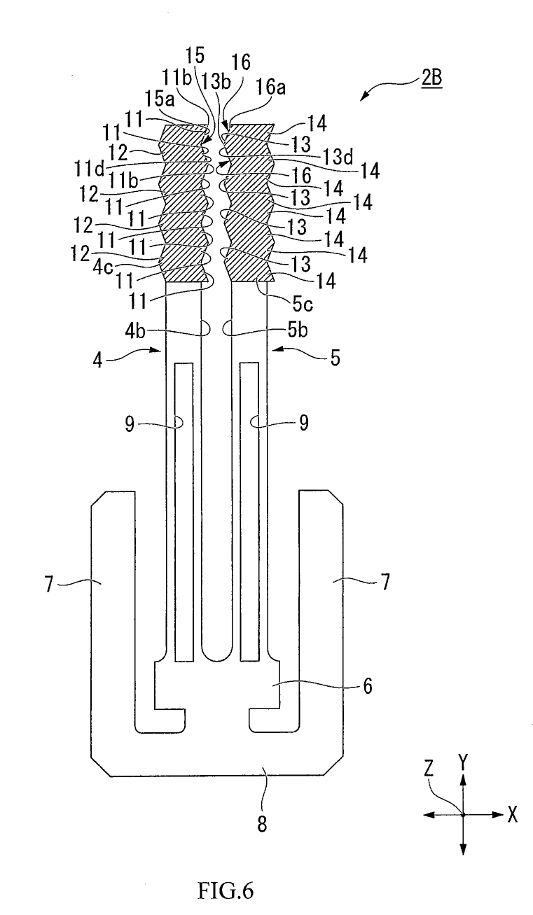

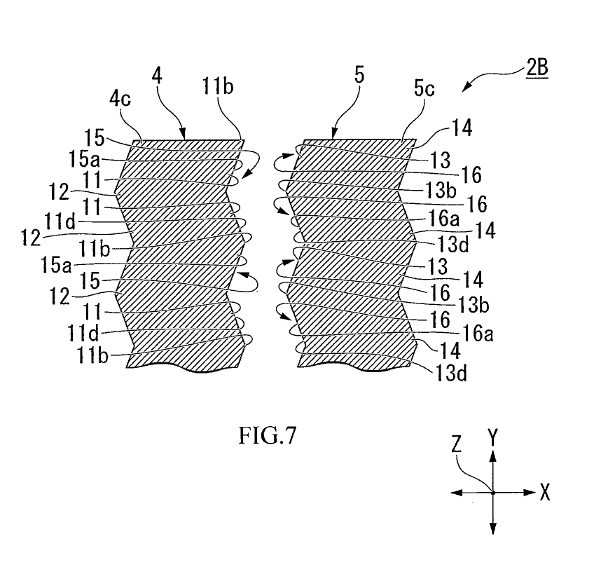

Next, a piezoelectric vibration piece 2B of the second variation is described with reference to FIGS. 6 and 7.

As shown in FIG. 6, in the piezoelectric vibration piece 2B, a plurality of the first inwardly bulging portions 11 and a plurality of the second inwardly bulging portions 13 are formed in the longitudinal direction Y, the numbers of the formed inwardly bulging portions 11, 13 being equal, which is four in the shown example. As shown in FIG. 7, the inwardly bulging portions 11, 13 are opposite to each other in the width direction X; the amounts of bulge of the inwardly bulging portions 11, 13 individually depend on the position in the longitudinal direction Y; and the bulging surfaces 11d, 13d of the inwardly bulging portions 11, 13 are formed in a shape that follows each other.

The amount of bulge of the second inwardly bulging portion 13 gradually increases from the both ends to the center in the longitudinal direction Y. In the shown example, the amount of bulge at the both ends of the second inwardly bulging portion 13 is zero, and the shape in the plan view of the bulging surface 13d of the second inwardly bulging portion 13 is linear and sloped with respect to the longitudinal direction Y and bends at the center.

On the other hand, the amount of bulge of the first inwardly bulging portion 11 gradually decreases from the both ends to the center in the longitudinal direction Y. In the shown example, the amount of bulge at the center of the first inwardly bulging portion 11 is zero, and the shape in the plan view of the bulging surface 11d of the first inwardly bulging portion 11 is linear and sloped with respect to the longitudinal direction Y and bends at the center.

Also, the amount of bulge at the end edges in the longitudinal direction Y of the first inwardly bulging portion 11 and the amount of bulge at the center in the longitudinal direction Y of the second inwardly bulging portion 13 are equal to each other.

The inwardly bulging portions 11 (and 13) adjacent to each other in the longitudinal direction Y are continuously placed with no space in between and with the end edges in the longitudinal direction Y connected to each other.

Also, the first relief portions 15 and the second relief portions 16 are provided with the bulging surfaces 11d, 13d as the wall surfaces 15a, 16a, respectively, by forming the bulging surfaces 11d, 13d of the inwardly bulging portions 11, 13 in a shape that follows each other as described above.

Also, as shown in FIG. 6, the same numbers of the first outwardly bulging portions 12 and second outwardly bulging portions 14 as those of the first inwardly bulging portions 11 and second inwardly bulging portions 13, respectively, the number being four in the shown example, are formed. As described above, the first outwardly bulging portions 12 are at the same positions in the longitudinal direction Y as the second inwardly bulging portions 13. Accordingly, the first inwardly bulging portions 11 and the first outwardly bulging portion 12 are at the same positions in the longitudinal direction Y. Also, as described above, the second outwardly bulging portions 14 are at the same positions in the longitudinal direction Y as the first inwardly bulging portions 11. Accordingly, the second inwardly bulging portions 13 and the second outwardly bulging portions 14 are at the same positions in the longitudinal direction Y.

As described above, according to the piezoelectric vibration piece 2B in accordance with the variation, forming the bulging surfaces 11d, 13d of the inwardly bulging portions 11, 13 in a shape that follows each other provides the first relief portions 15 and the second relief portions 16 with the bulging surfaces 11d, 13d as the wall surfaces 15a, 16a, respectively, which eliminates the need for making the positions in the longitudinal direction Y of the first inwardly bulging portions 11 and the second inwardly bulging portions 13 different from each other, allowing a plurality of the inwardly bulging portions 11, 13 to be formed continuously in the longitudinal direction Y in the tip portions 4c, 5c of the vibrating arms 4, 5.

Also, since the amount of bulge of the second inwardly bulging portion 13 gradually increases from the both ends to the center in the longitudinal direction Y and the amount of bulge of the first inwardly bulging portion 11 gradually decreases from the both ends to the center in the longitudinal direction Y, the both ends in the longitudinal direction Y of the second inwardly bulging portion 13 are chamfered, which can further prevent the tip portions 4c, 5c from being in contact with each other when the vibrating arms 4, 5 vibrate.

Note that, in this variation, the amount of bulge of the second inwardly bulging portion 13 gradually increases from the both ends to the center in the longitudinal direction Y and the amount of bulge of the first inwardly bulging portion 11 gradually decreases from the both ends to the center in the longitudinal direction Y. However, this is not the limitation. Also, in this variation, the number of each of the first inwardly bulging portions 11 and the second inwardly bulging portions 13 formed in the longitudinal direction Y is four. However, this is not the limitation.

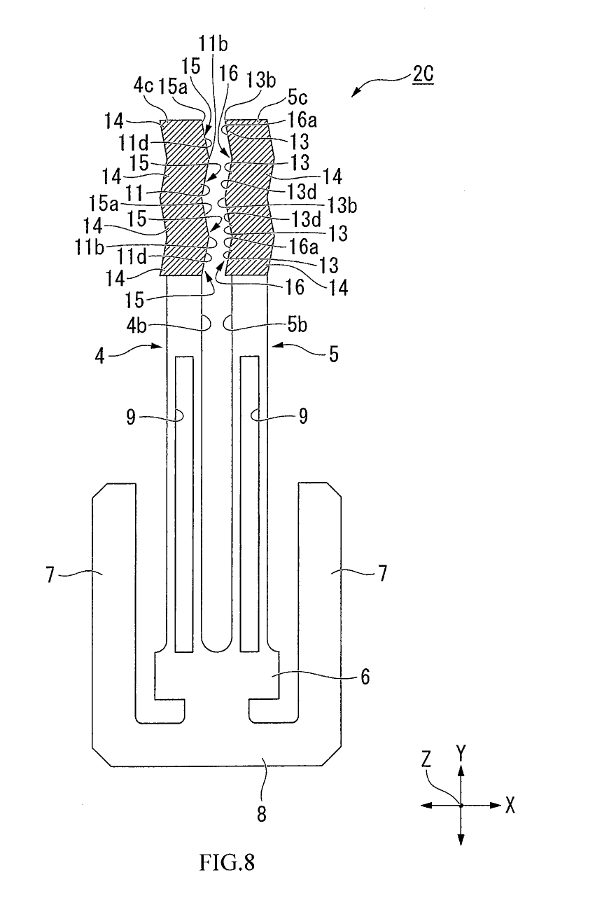

For example, as a piezoelectric vibration piece 2C shown in FIG. 8, it is also allowed that the amount of bulge of the first inwardly bulging portion 11 gradually increases from the both ends to the center in the longitudinal direction Y and the amount of bulge of the second inwardly bulging portion 13 gradually decreases from the both ends to the center in the longitudinal direction Y. Also, the number of each of the first inwardly bulging portions 11 and the second inwardly bulging portions 13 formed may be two, three, five or more.

Also, in this variation, the amount of bulge of the second inwardly bulging portion 13 gradually increases from the both ends to the center in the longitudinal direction Y and the amount of bulge of the first inwardly bulging portion 11 gradually decreases from the both ends to the center in the longitudinal direction Y. However, this is not the limitation. For example, it is also allowed that the amount of bulge of the second inwardly bulging portion 13 gradually increases from the end edge on the one side to the end edge on the other side and the amount of bulge of the first inwardly bulging portion 11 gradually decreases from the end edge on the other side to the end edge on the one side.

### (Oscillator)

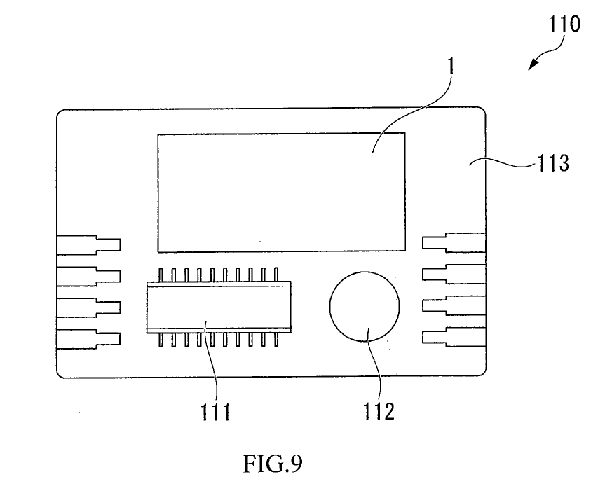

Next, an oscillator in accordance with an embodiment of the invention is described with reference to FIG. 9.

As shown in FIG. 9, the oscillator 110 of the embodiment includes the piezoelectric vibrator 1 configured as a resonator electrically connected to an integrated circuit 111. The oscillator 110 includes a circuit board 113 on which an electronic device component 112 such as a capacitor is mounted. The board 113 includes the integrated circuit for oscillator 111 mounted thereon, and the piezoelectric vibration piece of the piezoelectric vibrator 1 is mounted near the integrated circuit 111. The electronic device component 112, the integrated circuit 111 and the piezoelectric vibrator 1 are electrically connected via a wiring pattern not shown. Note that these components are molded with a resin not shown.

In the oscillator 110 thus configured, when a voltage is applied to the piezoelectric vibrator 1, the piezoelectric vibration piece in the piezoelectric vibrator 1 vibrates. This vibration is converted to an electric signal according to piezoelectric characteristics of the piezoelectric vibration piece. The electric signal is input to the integrated circuit 111. The input electric signal is subjected to various processing in the integrated circuit 111 and output as a frequency signal. Thus, the piezoelectric vibrator 1 functions as the resonator.

Also, selective setting on demand of the configuration of the integrated circuit 111, e.g., a real time clock (RTC) module etc., allows addition of the function of controlling date and time of activation of the device in question or an external device or of providing time information, calendar information and the like, to the function as a single-function oscillator for timepiece.

According to the oscillator 110 of the embodiment, including the piezoelectric vibrator 1 allows manufacturing of the oscillator 110 with high quality and small size.

### (Electronic Device)

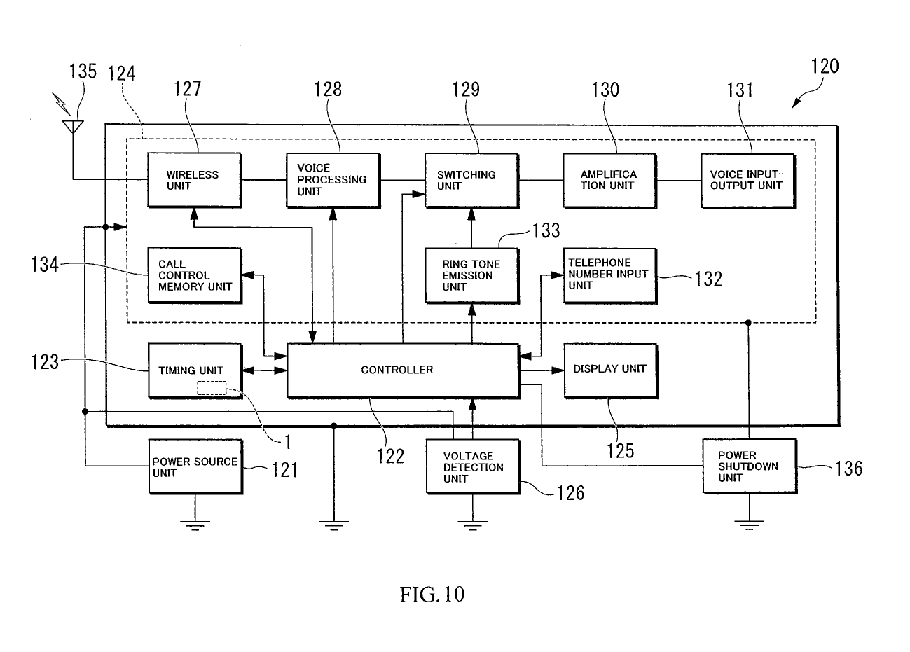

Next, an electronic device in accordance with an embodiment of the invention is described with reference to FIG. 10. As an example of the electronic device, a portable information device 120 including the above-described piezoelectric vibrator 1 is described.

The portable information device 120 of the embodiment is formed by extending and improving the capability of a wristwatch in conventional art and represented by, for example, a mobile phone. The portable information device 120 has an appearance similar to the wristwatch and includes a liquid crystal display in a portion corresponding to a timepiece face, on the screen of which current time and the like can be displayed. Also, in using the device 120 as communication device, the same level of communication as the mobile phone in conventional art can be performed by removing the device 120 from the wrist and using a speaker and microphone built into the inside of the band. However, the device 120 is much smaller and lighter than the conventional mobile phone.

Next, the configuration of the portable information device 120 of the embodiment is described. As shown in FIG. 10, the portable information device 120 includes the piezoelectric vibrator 1 and a power supply 121 for supplying power. The power supply 121 includes a lithium secondary cell, for example. To the power supply 121, a controller 122 for performing various controls, a timer 123 for counting time or the like, a communication section 124 for communicating with the outside, a display 125 for displaying various information and a voltage detector 126 for detecting voltage of these function sections are connected in parallel. Then, these function sections are supplied with power from the power supply 121.

The controller 122 controls the function sections to perform system-wide operation control including transmitting/receiving sound data and measuring/displaying current time. Also, the controller 122 includes a ROM in which a program is previously written, a CPU for reading and executing the program written in the ROM, a RAM used as work area for the CPU and the like.

The timer 123 includes the integrated circuit including oscillator, register, counter and interface circuits and the like, and the piezoelectric vibrator 1. When a voltage is applied to the piezoelectric vibrator 1, the piezoelectric vibration piece vibrates, then the vibration is converted to an electric signal according to piezoelectric characteristics of the crystal, and then the electric signal is input to the oscillator circuit. The output of the oscillator circuit is binarized and counted by the resister and counter circuits. Then, signal transmission/reception is performed with the controller 122 via the interface circuit, and the current time, current date or calendar information and the like are displayed on the display 125.

The communication section 124 has the same level of function as the conventional mobile phone and includes a wireless transmitter/receiver 127, a sound processor 128, a switcher 129, an amplifier 130, a sound input/output section 131, a telephone number input section 132, a ring tone generator 133 and a call control memory 134.

The wireless transmitter/receiver 127 transmits/receives various data including sound data to/from a base station via an antenna 135. The sound processor 128 encodes/decodes a sound signal input from the wireless transmitter/receiver 127 or the amplifier 130. The amplifier 130 amplifies a signal input from the sound processor 128 or the sound input/output section 131 to a predetermined level. The sound input/output section 131, including a speaker, a microphone and the like, amplifies a ring tone or a received sound and collects a sound.

The ring tone generator 133 generates a ring tone in response to a call from the base station. The switcher 129, only when a call is incoming, switches the connection of the amplifier 130 from the sound processor 128 to the ring tone generator 133 to cause a ring tone generated by the ring tone generator 133 to be output to the sound input/output section 131 through the amplifier 130.

The call control memory 134 stores a program relating to outgoing/incoming call control in the communication. Also, the telephone number input section 132 includes number keys of 0 to 9 and other keys, for example. By pressing these number keys or the like, the telephone number of a called party or the like is input.

When a voltage applied by the power supply 121 to the function sections including the controller 122 falls below a predetermined value, the voltage detector 126 detects the voltage drop and notifies the controller 122. The predetermined value is a value preset as a minimum voltage required for stable operation of the communication section 124, for example, about 3 V. When notified of the voltage drop by the voltage detector 126, the controller 122 stops the operation of the wireless transmitter/receiver 127, the sound processor 128, the switcher 129 and the ring tone generator 133. Especially, stopping the operation of the wireless transmitter/receiver 127 that consumes much power is essential. Furthermore, the display 125 displays a message that the communication section 124 is inoperable due to insufficient battery power.

Thus, the voltage detector 126 and the controller 122 can stop the operation of the communication section 124 and display a message notifying of this operation stop on the display 125. This message may be a text message or may be a “x” marked on a telephone icon shown in the upper portion of the screen of the display 125 for more intuitive display.

Note that, by including a power supply interrupter 136 that can selectively cut off power for a portion relating to the function of the communication section 124, the function of the communication section 124 can be more reliably stopped.

According to the portable information device 120 of the embodiment, including the piezoelectric vibrator 1 allows manufacturing of the portable information device 120 with high quality and small size.

### (Radio-Controlled Timepiece)

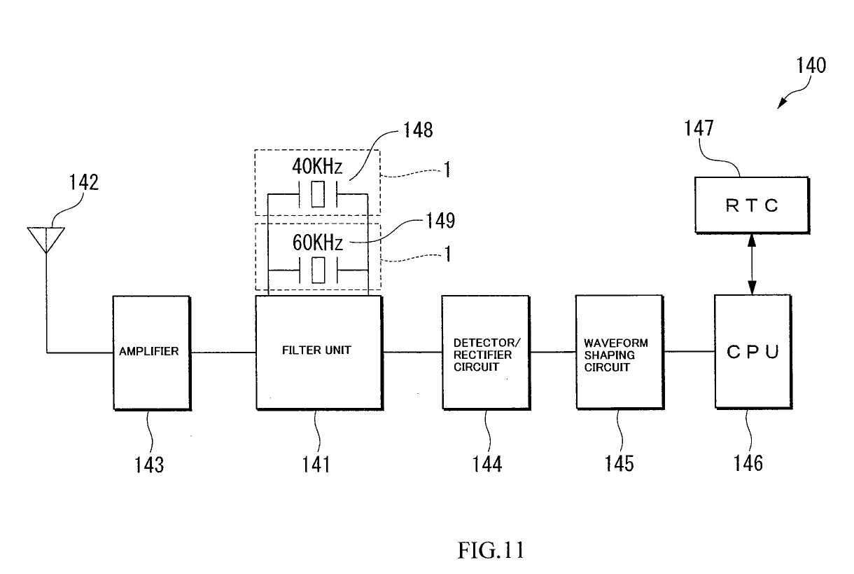

Next, a radio-controlled timepiece in accordance with an embodiment of the invention is described with reference to FIG. 11.

As shown in FIG. 11, the radio-controlled timepiece 140 of the embodiment is a timepiece that includes the piezoelectric vibrator 1 electrically connected to a filter 141 and is capable of receiving a standard wave including time information to automatically correct the displayed time.

In Japan, there are two transmitting stations for transmitting a standard wave. One of the stations is located in Fukushima prefecture (40 kHz), and the other is located in Saga prefecture (60 kHz), which are transmitting respective standard waves. A long wave such as 40 or 60 kHz has a combination of the property of propagating on the surface of the Earth and the property of propagating while reflecting between an ionosphere and the surface of the Earth, providing a wide propagation range, so the whole of Japan is covered by the above-described two transmitting stations.

The functional configuration of the radio-controlled timepiece 140 is described below in detail.

An antenna 142 receives a standard wave of a long wave of 40 or 60 kHz. The standard wave of the long wave is formed by amplitude-modulating a carrier wave of 40 or 60 kHz by time information called time code. The received standard wave of the long wave is amplified by an amplifier 143 and filtered and tuned by the filter 141 including a plurality of piezoelectric vibrators 1.

The piezoelectric vibrator 1 of the embodiment includes crystal resonators 148, 149 having resonance frequencies of 40 and 60 kHz, respectively, which are equal to the carrier frequencies.

Furthermore, the filtered signal of a predetermined frequency is detected and demodulated by a detector/rectifier 144.

Then, a time code is extracted through a waveform shaper 145 and counted by a CPU 146. The CPU 146 reads information, such as the current year, current accumulated days, current day of the week and current time. The read information is reflected by a RTC 148 that shows accurate time information.

Since the frequency of the carrier wave is 40 or 60 kHz, a vibrator having the above-described tuning-fork type structure is suitable for the crystal resonators 148, 149.

Note that the above description is for the case in Japan. In other countries, a standard wave of a long wave is used at a different frequency. For example, in Germany, a standard wave of 77.5 kHz is used. So, in order to include in a mobile device the radio-controlled timepiece 140 that can be used in other countries, another piezoelectric vibrator 1 for a frequency different from those for Japan is additionally required.

According to the radio-controlled timepiece 140 of the embodiment, including the piezoelectric vibrator 1 allows manufacturing of the radio-controlled timepiece 140 with high quality and small size.

It should be understood that the technical scope of the invention should not be limited to the above-described embodiment and that various modifications can be made without departing from the spirit of the invention.

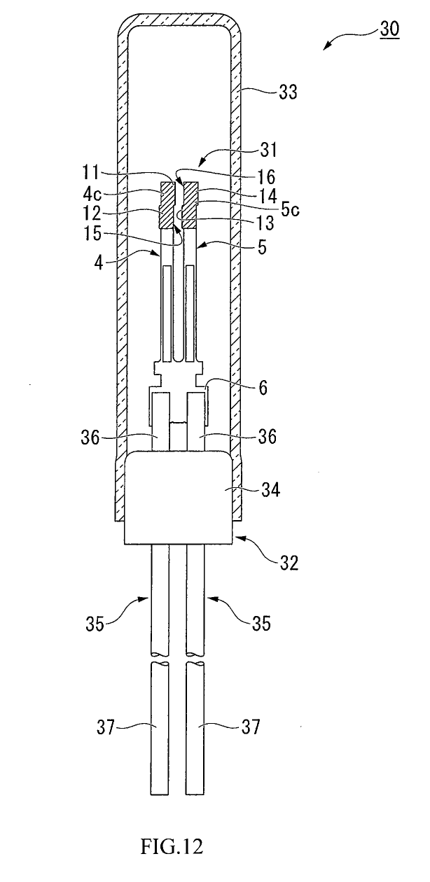

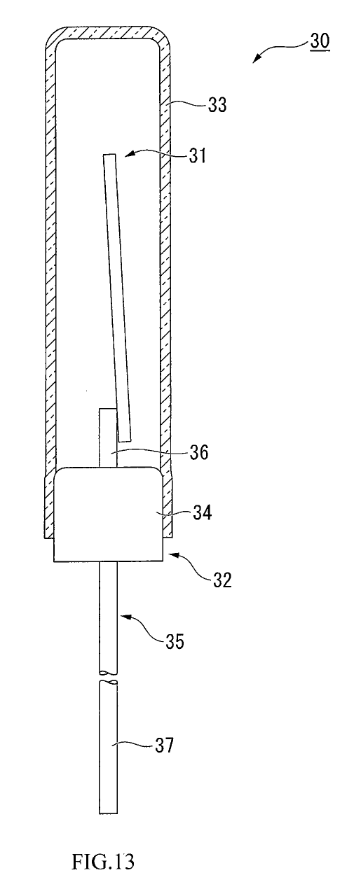

For example, in the above-described embodiment, the piezoelectric vibrator 1 is the surface-mount type. However, the piezoelectric vibrator 1 may also be a cylinder type as shown in FIGS. 12 and 13 or other type.

This piezoelectric vibrator 30 includes: a piezoelectric vibration piece 31; a plug 32 on which the piezoelectric vibration piece 31 is mounted; and a case 33 for hermetically enclosing the piezoelectric vibration piece 31 in cooperation with the plug 32.

Unlike the piezoelectric vibration piece 2 of the above-described embodiment, the piezoelectric vibration piece 31 does not include the side bases 7, and the mount portions of the electrode films are formed in the base 6.

The case 33 is formed in a cylinder shape with a closed top and, with the piezoelectric vibration piece 31 contained therein, is press-fitted to the circumference surface of a stem 34, described later, of the plug 32 to be fittingly secured.

The plug 32 includes: the cylindrically shaped stem 34 for hermetically sealing the case 33; two lead terminals 35 arranged in parallel to pass through the stem 34; and insulating filling material not shown filling the stem 34 to secure the lead terminals 35 to the stem 34.

One-end side of the two lead terminals 35 with respect to the stem 34 are inner-leads 36 mechanically joined to and electrically connected to the piezoelectric vibration piece 31 for mounting, and the other-end side of the two lead terminals 35 are outer-leads 37 to be electrically connected to the outside.

The inner-leads 36 are mounted on the mount portions of the electrode films of the piezoelectric vibration piece 31 via, for example, bonding sections not shown formed by melting a finishing film (high melting point solder plating) or the like.

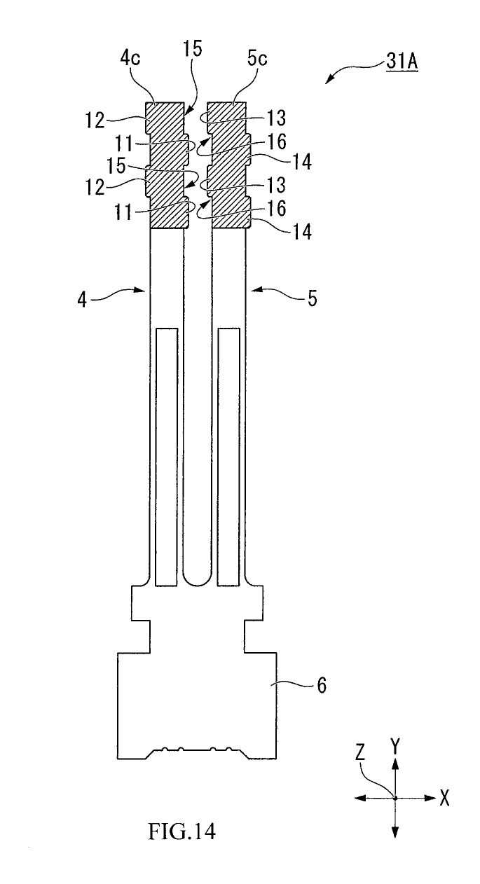

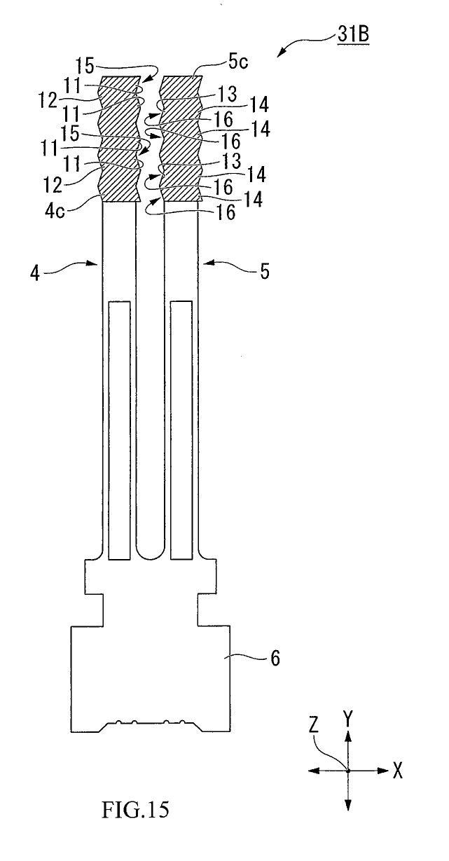

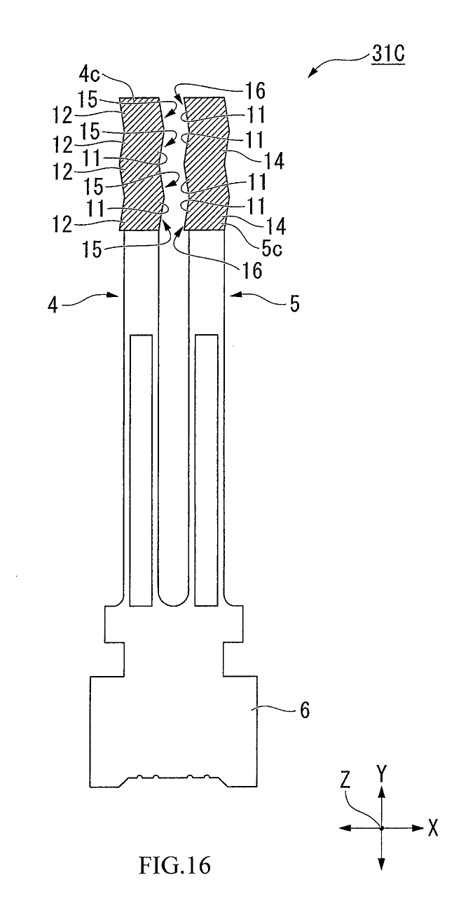

Note that, even in the piezoelectric vibration piece 31 without the side bases 7 as described above, the inwardly bulging portions 11, 13 and the outwardly bulging portions 12, 14 can be configured similarly to the piezoelectric vibration pieces 2A, 2B and 2C shown in FIGS. 5 to 8, as shown by piezoelectric vibration pieces 31A, 31B and 31C shown in FIGS. 14 to 16.

Also, in the above-described embodiment, the weight metal films 17 are formed on the piezoelectric vibration piece 31. However, the weight metal films 17 is optional.

Also, in the above-described embodiment, the amount of depression of the first relief portion 15 is equal to the amount of bulge of the second inwardly bulging portion 13 over the entire length in the longitudinal direction Y. However, this is not a limitation. The amount of depression of the first relief portion 15 may not be equal to, or may be less or more than the amount of bulge of the second inwardly bulging portion 13 over some or all of the length in the longitudinal direction Y.

Furthermore, in the above-described embodiment, the amount of depression of the second relief portion 16 is equal to the amount of bulge of the first inwardly bulging portion 11 over the entire length in the longitudinal direction Y. However, this is not a limitation. The amount of depression of the second relief portion 16 may not be equal to, or may be less or more than the amount of bulge of the first inwardly bulging portion 11 over some or all of the length in the longitudinal direction Y.

Also, without departing from the spirit of the invention, any of the components in the above-described embodiment may be replaced with a known component as appropriate. Also, any combination of the above-described variations may be used as appropriate.

1. A piezoelectric vibration piece comprising a pair of arms extending in parallel to each other from a base, wherein each of the arms has a weight added section which has at least two bulges projecting in the opposite directions at different longitudinal locations along the respective arm, and the at least two bulges are shaped and located such that both arms are equal in weight and a gravity center of the respective arms is situated on a center line running longitudinally through the respective arms and at a same longitudinal location along the respective arms.

2. The piezoelectric vibration piece according to claim 1, wherein at least one bulge projects from a respective arm toward the other arm such that the arms have opposing surfaces complementary in contour to each other and constant in distance between them along the weight added section.

3. The piezoelectric vibration piece according to claim 1, wherein the at least two bulges formed on the respective arms are equal in shape and weight.

4. The piezoelectric vibration piece according to claim 1, wherein the at least two bulges each have surfaces stepped up vertically from the arm.

5. The piezoelectric vibration piece according to claim 1, wherein the at least two bulges each have surfaces projecting progressively higher along a length of the arm.

6. The piezoelectric vibrator according to claim 1, wherein the weight added section is formed with a weight metal film.

7. The piezoelectric vibration piece according to claim 1, further comprising a pair of side bases extending in parallel to the arms.

8. A piezoelectric vibrator comprising the piezoelectric vibration piece according to claim 1.

9. An oscillator comprising the piezoelectric vibrator of claim 8 and electrically connected to an integrated circuit.

10. An electronic device comprising the piezoelectric vibrator of claim 8 electrically connected to a clock section of the electronic device.

11. A radio-controlled timepiece comprising the piezoelectric vibrator of claim 8 electrically connected to a filter of the timepiece.
